(19) United States
(12) Patent Application Publication
(10) Pub. No.: US 2026/0293067 A1
(43) Pub. Date: Sep. 24, 2026

(54) ELECTRONIC DEVICE FOR VEHICLE

(71) Applicant: HYUNDAI MOBIS CO., LTD., Seoul (KR)

(72) Inventors: Kang Il Ma, Yongin-si (KR); Hui Seong Choe, Yongin-si (KR); Won Ju Kim, Yongin-si (KR); Hae Jung Kim, Yongin-si (KR); Jang Hoon Lee, Yongin-si (KR); Chan Woong Jung, Yongin-si (KR); Sang Il Lee, Yongin-si (KR); Ji Min Song, Yongin-si (KR)

(73) Assignee: HYUNDAI MOBIS CO., LTD., Seoul (KR)

(21) Appl. No.: 19/323,158

(22) Filed: Sep. 9, 2025

(30) Foreign Application Priority Data
Mar. 24, 2025 (KR) 10-2025-0037424

(51) Int. Cl. H05K 7/20; B60R 16/033; H05K 5/00

(52) U.S. Cl. CPC H05K 7/20872; B60R 16/033; H05K 5/0026

(57) ABSTRACT

Provided is an electronic device for a vehicle including a housing including an upper accommodating space and a lower accommodating space disposed at an upper portion and a lower portion of the housing, respectively, wherein a cooling flow channel is disposed in respective portions of the upper accommodating space and the lower accommodating space, a plurality of PCBs selectively disposed in the upper accommodating space and the lower accommodating space, and a cover covering each of the upper portion and the lower portion of the housing.

This application claims the benefit of Korean Patent Application No. 10-2025-0037424, filed on Mar. 24, 2025, which is hereby incorporated by reference as if fully set forth herein.

### BACKGROUND OF THE DISCLOSURE

### Field of the Disclosure

The present disclosure relates to an electronic device for a vehicle having a plurality of electronic component circuits within a single housing.

### Discussion of the Related Art

In general, electronic components such as an advanced driver assistance system (ADAS), a cluster controller, a navigation system, an audio device, a video device, and the like may be installed in a cockpit of a vehicle. For example, the electronic components may be connected to cables to receive power, and locations thereof may be fixed by brackets installed inside the vehicle.

In one example, because the multiple electronic components are installed in a limited space, there are problems such as poor assemblability during initial installation and maintenance, and increased weight and labor because of the various brackets required for the location fixation.

In addition, a lot of heat is generated by circuit components installed in the electrical components, and heat dissipating components such as a heat sink, a heat dissipating fan, and the like installed to dissipate such heat increase weight and cost and cause noise.

In addition, as the cables respectively connected to the electronic components are distributed, a main cable is required to connect the distributed cables to each other. This increases a length of the cable, which increases material cost and weight.

### SUMMARY OF THE DISCLOSURE

Embodiments of the present disclosure may provide an electronic device for a vehicle that reduces a weight and work hours by integrating and arranging circuit components of electronic components installed in a cockpit of the vehicle in one housing to reduce the number of brackets for fixing the housing into the vehicle.

Embodiments of the present disclosure may provide an electronic device for a vehicle that reduces a material cost and a weight because, as a plurality of PCBs connected to power supply cables are installed inside one housing, a cable length may be reduced compared to that of an electronic device in which one PCB is installed in one housing.

Embodiments of the present disclosure may provide an electronic device for a vehicle that may omit a heat sink and a heat dissipating fan as a cooling flow channel and a cooling block for exchange of heat generated from heat generating elements are arranged within a housing.

Embodiments of the present disclosure may provide an electronic device for a vehicle that, as a heat sink and a heat dissipating fan may be omitted, may reduce a weight and a cost of a product, and solve noise occurring when the heat dissipating fan is in operation.

Problems to be solved in the present disclosure are not limited to the problems mentioned above, and other problems not mentioned may be clearly understood by a person having ordinary skill in the technical field to which the present disclosure belongs from a description below.

Embodiments of the present disclosure provide an electronic device for a vehicle including a housing including an upper accommodating space and a lower accommodating space disposed at an upper portion and a lower portion of the housing, respectively, wherein a cooling flow channel is disposed in respective portions of the upper accommodating space and the lower accommodating space, a plurality of PCBs selectively disposed in the upper accommodating space and the lower accommodating space, and a cover covering each of the upper portion and the lower portion of the housing.

According to the embodiments of the present disclosure, provided is the electronic device for the vehicle that reduces the weight and the work hours by integrating and arranging the circuit components of the electronic components installed in the cockpit of the vehicle in one housing to reduce the number of brackets for fixing the housing into the vehicle.

According to the embodiments of the present disclosure, provided is the electronic device for the vehicle that reduces the material cost and the weight because, as the plurality of PCBs connected to the power supply cables are installed inside one housing, the cable length may be reduced compared to that of the electronic device in which one PCB is installed in one housing.

According to the embodiments of the present disclosure, provided is the electronic device for the vehicle that may omit the heat sink and the heat dissipating fan as the cooling flow channel and the cooling block for the exchange of heat generated from the heat generating elements are arranged within the housing.

According to the embodiments of the present disclosure, provided is the electronic device for the vehicle that, as the heat sink and the heat dissipating fan may be omitted, may reduce the weight and the cost of the product, and solve the noise occurring when the heat dissipating fan is in operation.

Effects of the embodiments of the present disclosure are not limited to the effects mentioned herein, and other effects not mentioned will be clearly understood by those skilled in the art from a description below.

### BRIEF DESCRIPTION OF THE DRAWINGS

FIG. 1 is a perspective view of an electronic device for a vehicle according to an embodiment of the present disclosure.

FIG. 2 is an exploded perspective view of FIG. 1.

FIG. 3 is a plan perspective view of a housing according to an embodiment of the present disclosure.

FIG. 4 is a rear perspective view of a housing illustrated in FIG. 3.

FIG. 5 is a plan view of an electronic device for a vehicle according to an embodiment of the present disclosure with an upper cover separated.

FIG. 6 is an exploded perspective view of FIG. 5.

FIG. 7 is a cross-sectional view of an electronic device for a vehicle taken along a line A-A′ in FIG. 5.

FIG. 8 is a cross-sectional view of an electronic device for a vehicle according to another embodiment of the present disclosure.

FIG. 9 is a diagram illustrating an assembly structure of a cooling block according to an embodiment of the present disclosure.

FIG. 10 is a diagram illustrating an assembly structure of a cooling block according to another embodiment of the present disclosure.

FIG. 11 is a diagram schematically illustrating a coolant flow of an electronic device for a vehicle according to an embodiment of the present disclosure.

### DETAILED DESCRIPTION OF THE DISCLOSURE

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. Names of the respective elements used in the following explanations may be selected only for convenience of writing the specification and may be thus different from those used in actual products. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

The shapes, sizes, dimensions (e.g., length, width, height, thickness, radius, diameter, area, etc.), ratios, angles, number of elements, ratios, angles, numbers, and the like, which are illustrated in the drawings to describe various example embodiments of the present disclosure are merely given by way of example. Therefore, the present disclosure is not limited to the illustrations in the drawings. Any implementation described herein as an “example” is not necessarily to be construed as preferred or advantageous over other implementations.

The word “exemplary” is used to mean serving as an example or illustration. Embodiments are example embodiments. Aspects are example aspects. Any implementation described herein as an “example” is not necessarily to “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various embodiments of the present disclosure will be described in detail with reference to the attached drawings.

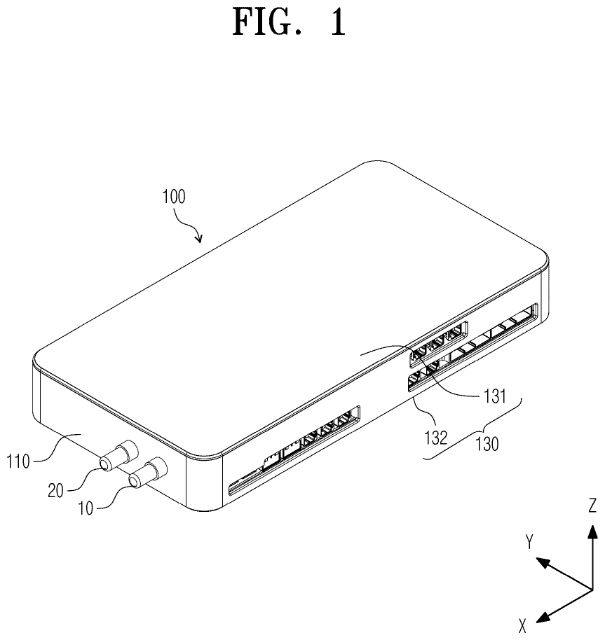

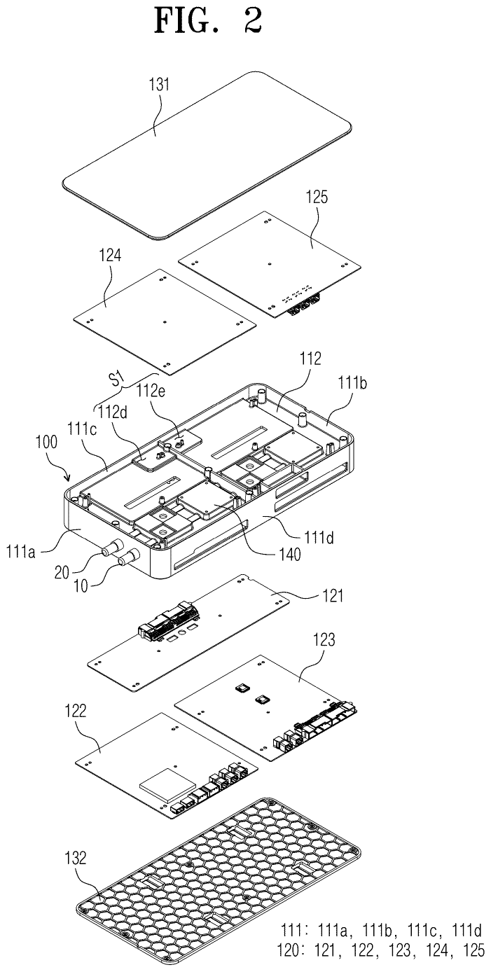

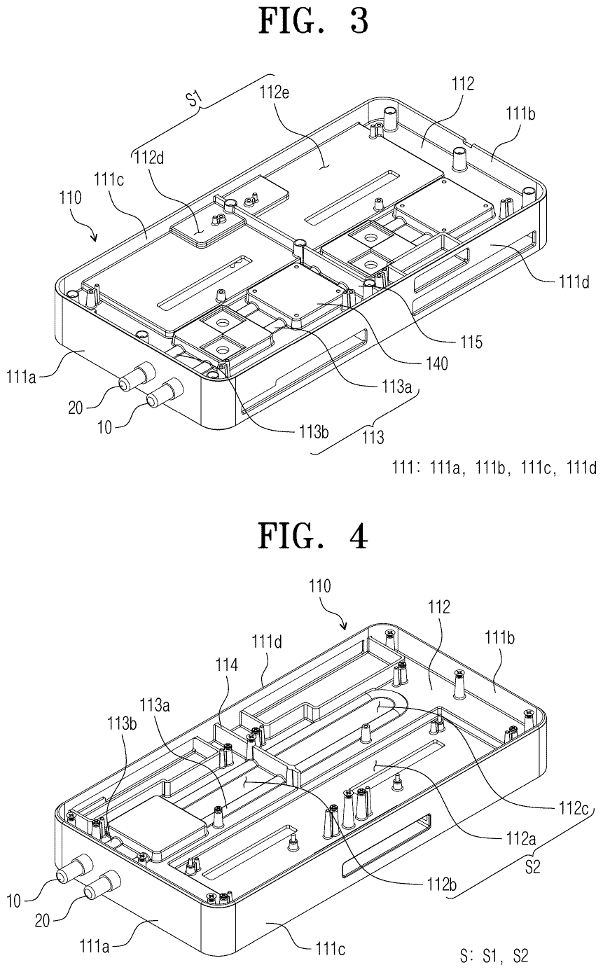

FIG. 1 is a perspective view of an electronic device for a vehicle according to an embodiment of the present disclosure, FIG. 2 is an exploded perspective view of FIG. 1, FIG. 3 is a plan perspective view of a housing according to an embodiment of the present disclosure, and FIG. 4 is a rear perspective view of a housing illustrated in FIG. 3.

Referring to FIGS. 1 to 4, an electronic device 100 for a vehicle may include a housing 110, a PCB 120, and a cover 130.

The electronic device 100 for the vehicle in the present embodiment may be used to integrate and arrange circuit components of electronic components installed in a cockpit of the vehicle, such as an advanced driver assistance system (ADAS), a cluster controller, a navigation system, an audio device, and a video device, within the single housing 110.

The housing 110 may have an upper accommodating space S1 and a lower accommodating space S2 defined therein in upper and lower portions, respectively, and a cooling flow channel 113 may be disposed in portions of the upper accommodating space S1 and the lower accommodating space S2. For example, the housing 110 may include an inlet port 10 into which coolant of the vehicle is introduced and a discharge port 20 through which coolant is discharged, and the cooling flow channel 113 may include an inlet portion 113a in fluidic communication with the inlet port 10 and a discharge portion 113b in fluidic communication with the inlet portion 113a and the discharge port 20. That is, when coolant is introduced into the inlet port 10 from the outside, coolant may pass through the inlet portion 113a and the discharge portion 113b and be discharged into the discharge port 20.

Because of such a configuration of the cooling flow channel 113, heat generated from heat generating elements disposed inside the housing 110 may be exchanged without a heat sink or a heat dissipating fan. Therefore, the heat sink and the heat dissipating fan may be omitted, so that a weight and a cost of a product may be reduced, and a problem of noise occurring when the heat dissipating fan is in operation may be solved.

The housing 110 may be made of a metal material such as aluminum or copper. When the housing 110 is made of the metal material with good thermal conductivity as such, the electronic device 100 for the vehicle with improved heat dissipation efficiency may be provided.

The housing 110 may include a side wall 111 and a partitioning portion 112.

The side wall 111 may include a first side wall 111a, a second side wall 111b, a third side wall 111c, and a fourth side wall 111d. In a following description, an X-axis direction may refer to a front and rear direction, a Y-axis direction may refer to a left and right direction, and a Z-axis direction may refer to a vertical direction.

The first side wall 111a may be disposed at a front side in the drawing, and may be formed in a quadrangular plate shape that is elongated in the Y-axis direction. The second side wall 111b may be disposed to be spaced apart from the first side wall 111a and positioned at a rear side in the drawing, and may be formed in a shape corresponding to the first side wall 111a. The third side wall 111c may be disposed at a left side in the drawing, and may connect the first side wall 111a with the second side wall 111b at one side. The fourth side wall 111d may be disposed at a right side in the drawing, and may connect the first side wall 111a with the second side wall 111b at the other side.

By such first to fourth side walls 111a, 111b, 111c, and 111d, the housing 110 may be formed in a quadrangular box shape with an accommodating space S defined therein.

The partitioning portion 112 may be horizontally disposed inward of the side wall 111 to partition the accommodating space S into the upper accommodating space S1 and the lower accommodating space S2. Here, the cooling flow channel 113 may be installed on the partitioning portion 112. For example, the cooling flow channel 113 may be formed in a shape of a pipe intersecting the partitioning portion 112 that partitions the upper accommodating space S1 and the lower accommodating space S2 from each other, so that an upper portion thereof may be positioned in the upper accommodating space S1 and a lower portion thereof may be positioned in the lower accommodating space S2. That is, the cooling flow channel 113 may be formed integrally with the partitioning portion 112.

As such, as the portions of the cooling flow channel 113 are disposed in both the upper accommodating space S1 and the lower accommodating space S2, an entire space inside the housing 110 may be heat-exchanged with only one cooling flow channel 113, thereby improving a cooling efficiency.

Each of the upper accommodating space S1 and the lower accommodating space S2 may include a plurality of accommodating portions. For example, the lower accommodating space S2 may include a first accommodating portion 112a, a second accommodating portion 112b, and a third accommodating portion 112c, and the upper accommodating space S1 may include a fourth accommodating portion 112d and a fifth accommodating portion 112e.

The first accommodating portion 112a may be defined as a portion of the partitioning portion 112 is recessed toward the upper accommodating space S1. The first accommodating portion 112a may be disposed so as not to interfere with the cooling flow channel 113. For example, when the cooling flow channel 113 is disposed at a right side of the accommodating space S, the first accommodating portion 112a may be disposed at a left side of the accommodating space S so as to be elongated in the X-axis direction.

The second accommodating portion 112b and the third accommodating portion 112c may be separated from each other by a first partition wall 114 disposed between the first side wall 111a and the second side wall 111b of the lower accommodating space S2. In this regard, the first partition wall 114 may be formed so as not to interfere with the first accommodating portion 112a. That is, the first partition wall 114 may be formed with a length such that it does not reach the first accommodating portion 112a. This is to prevent interference with the first partition wall 114 when a first PCB 121, which will be described later, is inserted into the first accommodating portion 112a.

The fourth accommodating portion 112d and the fifth accommodating portion 112e may be separated from each other by a second partition wall 115 disposed between the first side wall 111a and the second side wall 111b of the upper accommodating space S1. In this regard, both side ends of the second partition wall 115 may be formed to be in contact with the third side wall 111c and the fourth side wall 111d, respectively. That is, the fourth accommodating portion 112d and the fifth accommodating portion 112e may define completely separated spaces by the second partition wall 115.

The PCB 120 may include a plurality of PCBs and the plurality of PCBs may be selectively disposed in the upper accommodating space S1 and the lower accommodating space S2. The number of PCBs 120 may be equal to the required number of electronic components. For example, when the electronic components are composed of the ADAS, the cluster controller, the navigation system, the audio device, and the video device, five PCBs 120 may be disposed, and when the electronic components are composed of the ADAS, the cluster controller, and the navigation system, three PCBs 120 may be disposed.

Hereinafter, for convenience of description, the PCB 120 installed in the first accommodating portion 112a will be referred to as the first PCB 121, the PCB 120 installed in the second accommodating portion will be referred to as a second PCB 122, the PCB 120 installed in the third accommodating portion 112c will be referred to as a third PCB 123, the PCB 120 installed in the fourth accommodating portion 112d will be referred to as a fourth PCB 124, and the PCB 120 installed in the fifth accommodating portion 112e will be referred to as a fifth PCB 125. Here, the first PCB 121 may be a main PCB 120 to which power is supplied.

The first PCB 121, the second PCB 122, the third PCB 123, the fourth PCB 124, and the fifth PCB 125 may be disposed in the first accommodating portion 112a, the second accommodating portion, the third accommodating portion 112c, the fourth accommodating portion 112d, and the fifth accommodating portion 112e, respectively. That is, one PCB 120 may be disposed in one accommodating portion. When the number of PCBs 120 is equal to or smaller than four, at least one of the first accommodating portion 112a, the second accommodating portion, the third accommodating portion 112c, the fourth accommodating portion 112d, and the fifth accommodating portion 112e may be empty.

The cover 130 may cover upper and lower portions of the housing 110. For example, the cover 130 may include an upper cover 131 and a lower cover 132, the upper cover 131 may shield the open upper accommodating space S1 of the housing 110, and the lower cover 132 may shield the lower accommodating space S2 of the housing 110.

The upper cover 131 and the lower cover 132 may be screw-coupled to the housing 110 via fastening members such as bolts. The upper cover 131 and the lower cover 132 may prevent moisture or foreign substances from penetrating into the housing 110 from the outside.

The cover 130 may be made of a metal or plastic material. When the cover 130 is made of the metal material such as aluminum or copper, a heat dissipation performance of the housing 110 may be improved, and when the cover 130 is made of the plastic material, the weight and the manufacturing cost may be reduced.

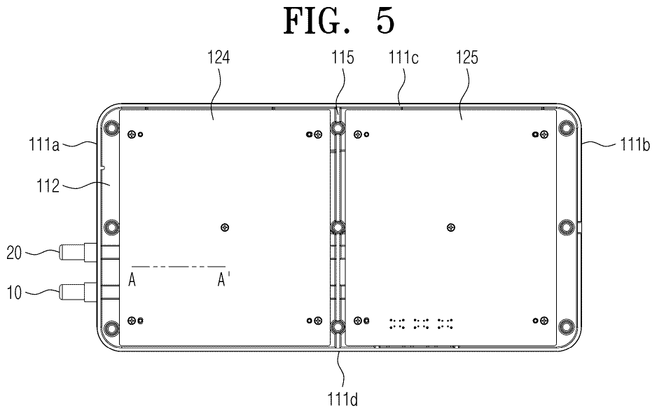

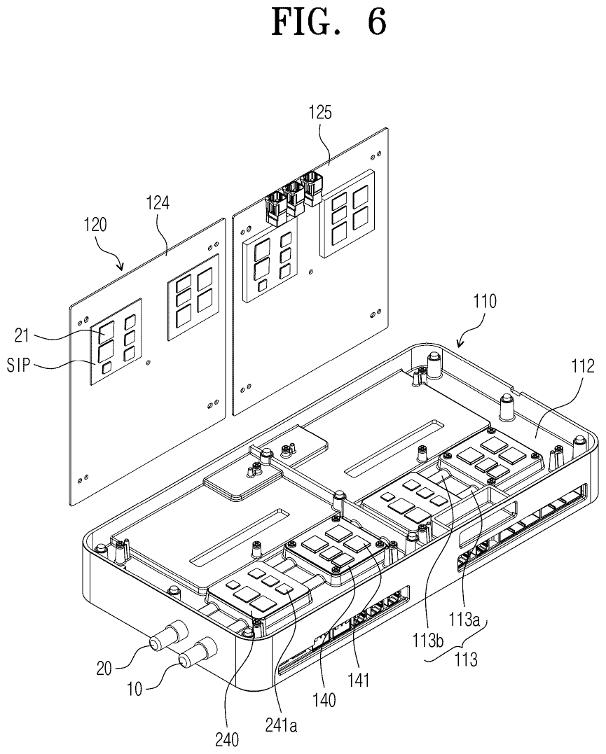

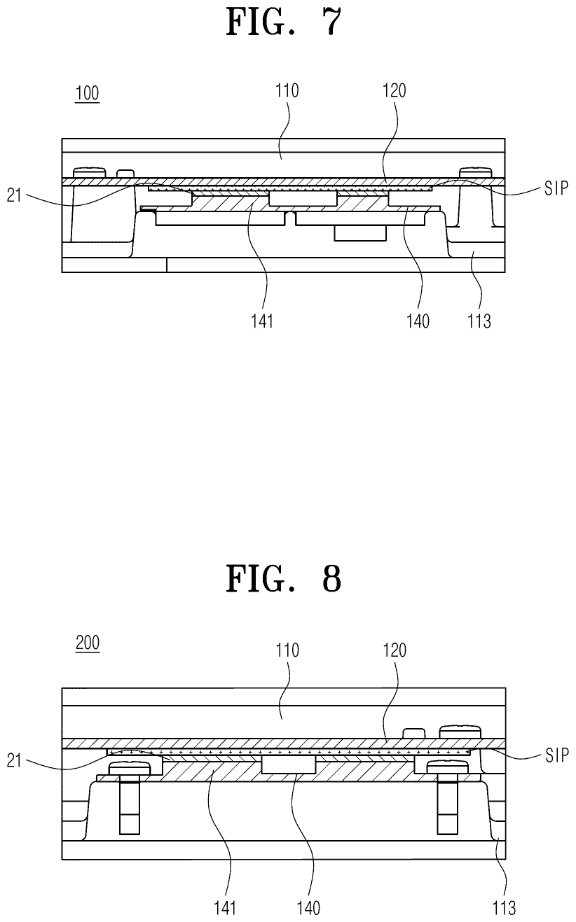

FIG. 5 is a plan view of an electronic device for a vehicle according to an embodiment of the present disclosure with an upper cover separated, FIG. 6 is an exploded perspective view of FIG. 5, and FIG. 7 is a cross-sectional view of an electronic device for a vehicle taken along a line A-A′ in FIG. 5.

Referring to FIGS. 5 to 7, the electronic device 100 for the vehicle may include each cooling block 140 and 240 inside the housing 110.

Each cooling block 140 and 240 may be made of a metal material such as aluminum, copper, and the like, and may be disposed to be in contact with a heat generating element 21 of the PCB 120 at a location where the cooling flow channel 113 is disposed. For example, an SIP equipped with the heat generating element 21 such as a CPU and a GPU may be installed on the PCB 120, and each cooling block 140 and 240 may include each protruding member 141 and 241a formed to be in contact with each heat generating element 21. For example, each protruding member 141 and 241a may be formed in a shape corresponding to that of the heat generating element 21.

As such, because each cooling block 140 and 240 is disposed on the cooling flow channel 113 and comes into direct contact with the heat generating element 21, the heat dissipation efficiency may be improved.

FIG. 8 is a cross-sectional view of an electronic device for a vehicle according to another embodiment of the present disclosure.

Referring to FIG. 8, an electronic device 200 for a vehicle may vary in a location and a shape of the heat generating element 21 depending on a required performance. That is, a vertical level at which the heat generating element 21 is located and a size of the heat generating element 21 may vary depending on design. Therefore, to maintain the heat dissipation performance, the shape of the protruding member 141 should be changed to match the structure of the heat generating element 21.

To correspond to the structure of such a heat generating element 21, the cooling block 140 may be detachable from the housing 110. When the cooling block 140 has a structure formed integrally with the housing 110, the entire housing 110 equipped with the cooling block 140 matching the structure of the heat generating element 21 should be replaced. On the other hand, in the case in which the cooling block 140 is formed to be detachable from the housing 110 as in the present embodiment, after manufacturing the cooling block 140 matching the structure of the heat generating element 21, only the cooling block 140 needs to be replaced from the housing 110, which reduces the manufacturing cost.

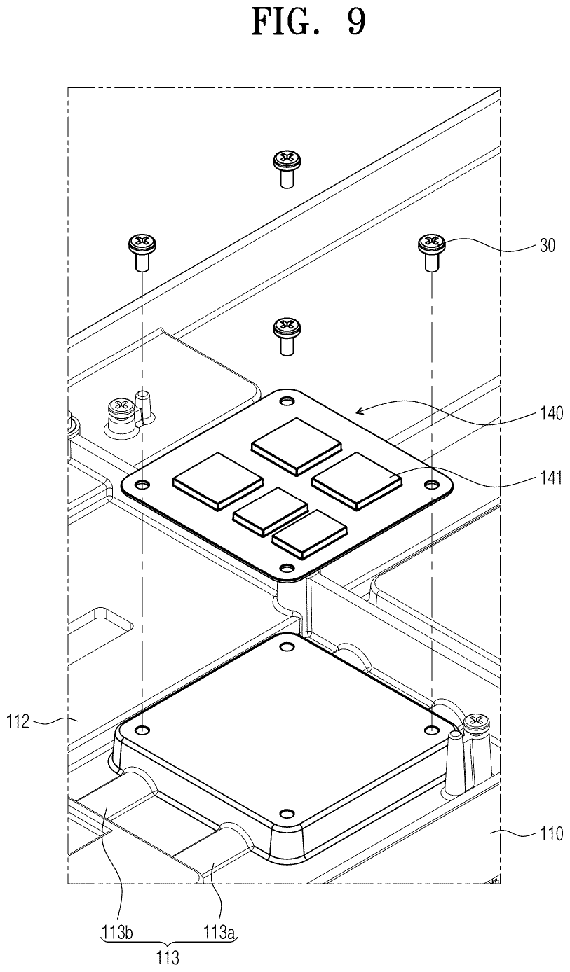

FIG. 9 is a diagram illustrating an assembly structure of a cooling block according to an embodiment of the present disclosure.

Referring to FIGS. 6 and 9, the cooling block 140 may be screw-coupled onto the partitioning portion 112 of the housing 110. For example, the cooling block 140 may be formed in a quadrangular plate shape with the protruding member 141 formed on top thereof, and each corner may be screw-coupled via a fastening member 30 such as a bolt. Therefore, the cooling block 140 may be installed so as to be detachable from the housing 110 by separation and coupling of the fastening member.

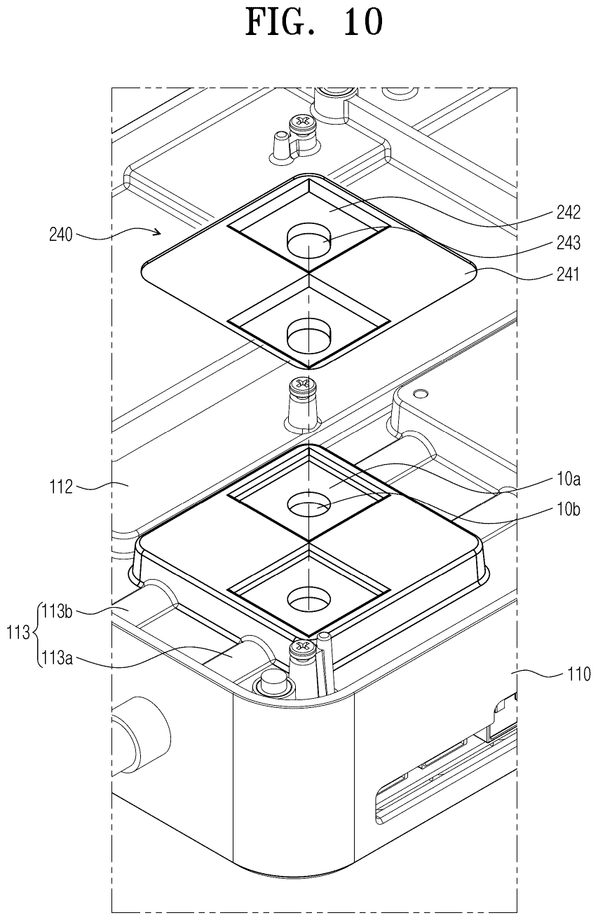

FIG. 10 is a diagram illustrating an assembly structure of a cooling block according to another embodiment of the present disclosure.

Referring to FIGS. 6 and 10, the cooling block 240 may be coupled onto the partitioning portion 112 of the housing 110 in a forcible fitting manner. For example, the cooling block 240 may include a base 241, a guide 242, and a coupling protrusion 243.

The base 241 may be formed in a quadrangular plate shape with the protruding member 241a formed on top thereof.

The guide 242 may be formed in a quadrangular plate shape and may protrude from a bottom of the base 241 in a direction in which the housing 110 is disposed. In the present embodiment, two guides 242 are illustrated, but one or two or more guides may be disposed.

The coupling protrusion 243 may be formed in a circular plate shape and may protrude from a bottom of the guide 242 in a direction in which the partitioning portion 112 of the housing 110 is disposed. The number of coupling protrusions 243 may be equal to the number of guides 242.

For assembly with the cooling block 240, the housing 110 may include a guide groove 10a into which the guide 242 is inserted, and a coupling groove 10b located within the guide groove 10a and into which the coupling protrusion 243 is forcibly fitted.

Therefore, when the cooling block 240 is gripped and the guide 242 is inserted into the guide groove 10a, an assembly location of the cooling block 140 may be guided, and when a pressuring force is applied in a downward direction to the cooling block 240, the coupling protrusion 243 may be forcibly fitted into the coupling groove 10b, so that the cooling block 240 may be stably coupled onto the housing 110. Conversely, when the cooling block 240 is gripped and a pulling force is applied thereto upward, the coupling protrusion 243 may be separated from the coupling groove 10b.

Such a forcible fitting manner does not require a separate fastening member, which facilitates assembly and disassembly.

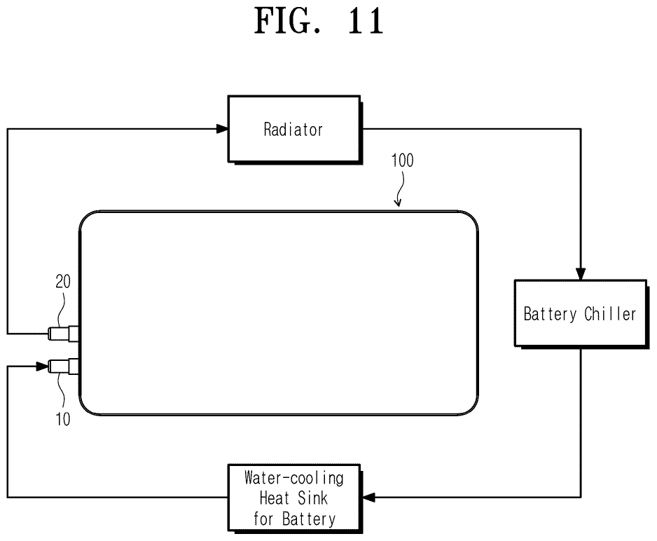

FIG. 11 is a diagram schematically illustrating a coolant flow of an electronic device for a vehicle according to an embodiment of the present disclosure.

Referring to FIG. 11, the electronic device 100 for the vehicle may receive coolant from a water-cooling heat sink for a battery via the inlet port 10 and supply the same to the cooling flow channel 113. Accordingly, heat generated from the plurality of PCBs 120 arranged on the cooling flow channel 113 may be exchanged to lower a temperature inside the housing 110.

Coolant whose temperature has increased via such a heat exchange may be discharged via the discharge port 20 and cooled while passing through a radiator and a battery chiller. Low-temperature coolant cooled as such may be supplied to the water-cooling heat sink for the battery again and circulated.

As described above, the electronic device 100 for the vehicle may integrate and arrange the circuit components of the electronic components installed in the cockpit of the vehicle in one housing 110 to reduce the number of brackets for fixing the housing 110 into the vehicle, thereby reducing the weight and work hours.

In addition, as the plurality of PCBs 120 connected to the power supply cables are installed inside one housing 110, a cable length may be reduced compared to that of an electronic device in which one PCB 120 is installed in one housing 110, and thus the material cost and the weight may be reduced.

In addition, as the cooling flow channel 113 and the cooling block 140 for exchange of heat generated from the heat generating elements 21 are arranged within the housing 110, the heat sink and the heat dissipating fan may be omitted, thereby reducing the weight and the cost of the product.

In addition, as the heat exchange becomes available without the heat dissipating fan, the noise occurring when the heat dissipating fan is in operation may be solved.

The embodiments of the present disclosure described above will be briefly described as follows.

According to embodiments of the present disclosure, provided is an electronic device for a vehicle including a housing including an upper accommodating space and a lower accommodating space disposed at an upper portion and a lower portion of the housing, respectively, wherein a cooling flow channel is disposed in respective portions of the upper accommodating space and the lower accommodating space, a plurality of PCBs selectively disposed in the upper accommodating space and the lower accommodating space, and a cover covering each of the upper portion and the lower portion of the housing.

According to embodiments of the present disclosure, the housing may include a side wall including a first side wall, a second side wall disposed to be spaced apart from the first side wall, a third side wall connecting the first side wall with the second side wall at one side, and a fourth side wall connecting the first side wall with the second side wall at a remaining side, wherein an accommodating space is defined inward by the first, second, third and fourth side walls, and a partitioning portion disposed horizontally inward of the side wall to partition the accommodating space into the upper accommodating space and the lower accommodating space.

According to embodiments of the present disclosure, the lower accommodating space may include a first accommodating portion defined as a portion of the partitioning portion is recessed toward the upper accommodating space.

According to embodiments of the present disclosure, the first accommodating portion may be defined so as not to interfere with the cooling flow channel.

According to embodiments of the present disclosure, the lower accommodating space may include a second accommodating portion and a third accommodating portion separated from each other by a first partition wall disposed between the first side wall and the second side wall, and the upper accommodating space may include a fourth accommodating portion and a fifth accommodating portion separated from each other by a second partition wall disposed between the first side wall and the second side wall.

According to embodiments of the present disclosure, the cooling flow channel may be formed in a shape of a pipe intersecting the partitioning portion, and have an upper portion thereof located in the upper accommodating space and a lower portion thereof located in the lower accommodating space.

According to embodiments of the present disclosure, the housing may include an inlet port where coolant of the vehicle is introduced and a discharge port where the coolant is discharged, and the cooling flow channel may include an inlet portion in fluidic communication with the inlet port and a discharge portion in fluidic communication with the inlet portion and the discharge port.

According to embodiments of the present disclosure, the housing may include a cooling block in contact with a heat generating element of each PCB at a location where the cooling flow channel is disposed.

According to embodiments of the present disclosure, the cooling block may be detachable from the housing.

According to embodiments of the present disclosure, the cooling block may include a plate-shaped base, at least one guide protruding from one surface of the base in a direction where the housing is disposed, and a coupling protrusion protruding from one surface of the at least one guide in the direction where the housing is disposed, and the housing may include a guide groove allowing the guide to be inserted thereinto, and a coupling groove located within the guide groove and allowing the coupling protrusion to be forcefully fitted thereinto.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. An electronic device for a vehicle, the electronic device comprising:
a housing including an upper accommodating space and a lower accommodating space disposed at an upper portion and a lower portion of the housing, respectively, wherein a cooling flow channel is disposed in respective portions of the upper accommodating space and the lower accommodating space;
a plurality of PCBs selectively disposed in the upper accommodating space and the lower accommodating space; and
a cover covering each of the upper portion and the lower portion of the housing.

2. The electronic device of claim 1, wherein the housing further includes:
a side wall including a first side wall, a second side wall disposed to be spaced apart from the first side wall, a third side wall connecting the first side wall with the second side wall at one side, and a fourth side wall connecting the first side wall with the second side wall at a remaining side, wherein an accommodating space is defined inward by the first, second, third and fourth side walls; and
a partitioning portion disposed horizontally inward of the side wall to partition the accommodating space into the upper accommodating space and the lower accommodating space.

3. The electronic device of claim 2, wherein the lower accommodating space includes a first accommodating portion defined as a portion of the partitioning portion is recessed toward the upper accommodating space.

4. The electronic device of claim 3, wherein the first accommodating portion is defined so as not to interfere with the cooling flow channel.

5. The electronic device of claim 3, wherein the lower accommodating space includes a second accommodating portion and a third accommodating portion separated from each other by a first partition wall disposed between the first side wall and the second side wall.

6. The electronic device of claim 3,
wherein the upper accommodating space includes a fourth accommodating portion and a fifth accommodating portion separated from each other by a second partition wall disposed between the first side wall and the second side wall.

7. The electronic device of claim 2, wherein the cooling flow channel is formed in a shape of a pipe intersecting the partitioning portion, and has an upper portion thereof located in the upper accommodating space and a lower portion thereof located in the lower accommodating space.

8. The electronic device of claim 2, wherein a cooling block is detachably coupled onto the partitioning portion of the housing.

9. The electronic device of claim 9,
wherein the cooling block includes a plate-shaped base, at least one guide protruding from one surface of the base in a direction where the housing is disposed, and a coupling protrusion protruding from one surface of the at least one guide in the direction where the housing is disposed, and
wherein the housing further includes a guide groove allowing the at least one guide to be inserted thereinto, and a coupling groove located within the guide groove and allowing the coupling protrusion to be forcefully fitted thereinto.

10. The electronic device of claim 1,
wherein the housing further includes an inlet port where coolant of the vehicle is introduced and a discharge port where the coolant is discharged, and
wherein the cooling flow channel includes an inlet portion in fluidic communication with the inlet port and a discharge portion in fluidic communication with the inlet portion and the discharge port.

11. The electronic device of claim 1, wherein the housing further includes a cooling block in contact with a heat generating element of each PCB at a location where the cooling flow channel is disposed.

12. The electronic device of claim 11, wherein the cooling block is detachable from the housing.

13. The electronic device of claim 11,
wherein the cooling block includes a plate-shaped base, at least one guide protruding from one surface of the base in a direction where the housing is disposed, and a coupling protrusion protruding from one surface of the at least one guide in the direction where the housing is disposed,
wherein the housing further includes a guide groove allowing the at least one guide to be inserted thereinto, and a coupling groove located within the guide groove and allowing the coupling protrusion to be forcefully fitted thereinto.

14. A cooling system of the electronic device of claim 10, wherein the outlet port and the inlet port are connected by at least one of a radiator, a battery chiller, and a heat sink for a battery between the outlet port and the inlet port.

15. The cooling system of the electronic device of claim 14, wherein the radiator, the battery chiller, and the heat sink for the battery are connected between the outlet port and the inlet port in series.
